(19) United States
(12) Patent Application Publication
(10) Pub. No.: US 2026/0255754 A1
(43) Pub. Date: Aug. 27, 2026

(54) LIGHT-EMITTING SUBSTRATE, BACKLIGHT MODULE, AND DISPLAY DEVICE

(71) Applicants: Hefei BOE Ruisheng Technology Co., Ltd., Hefei (Anhui) (CN); BOE TECHNOLOGY GROUP CO.,LTD., Beijing (CN)

(72) Inventors: Jie LEI, Beijing (CN); Jian TIAN, Beijing (CN); Chunjian LIU, Beijing (CN); Jianying ZHANG, Beijing (CN); Yajun MA, Beijing (CN)

(73) Assignees: Hefei BOE Ruisheng Technology Co., Ltd., Hefei (Anhui) (CN); BOE TECHNOLOGY GROUP CO.,LTD., Beijing (CN)

(21) Appl. No.: 18/995,338

(22) PCT Filed: Apr. 28, 2024
(86) PCT No.: PCT/CN2024/090252

§ 371 Date: Jan. 16, 2025

(30) Foreign Application Priority Data
May 31, 2023 (CN) 202310644988.4

(51) Int. Cl. H10H 29/49

(52) U.S. Cl. CPC H10H 29/49

(57) ABSTRACT

A light-emitting substrate, a backlight module, and a display device. The light-emitting substrate includes a base substrate, a plurality of first driving units, and a second driving unit, wherein the plurality of first driving units are arranged in an array, and the first driving units include a plurality of first connecting parts; the second driving unit includes a second connecting part and a plurality of first leads electrically connected to the second connecting part; the second driving unit is at least partially located between two adjacent first driving units in a first direction and is located between two adjacent first driving units in a second direction, and at least one first lead includes a test pad.

### CROSS-REFERENCE TO RELATED APPLICATION(S)

The present disclosure claims priority to Chinese Patent Application No. 202310644988.4 filed on May 31, 2023, the disclosure of which is incorporated herein by reference in its entirety as a part of this application.

### TECHNICAL FIELD

At least one embodiment of the present disclosure relates to a light-emitting substrate, a backlight module and a display device.

### BACKGROUND

In recent years, with the rapid development of MLED industry, MLED backlight is more and more widely used. MLED includes Mini-LED (typically between 50 μm and 300 μm in dimension) and Micro-LED (typically less than 50 μm in dimension). In comparison, the technology of Micro-LED is not yet mature, and the huge amount transfer technology is very difficult. Therefore, Mini-LED can be used as a transition product of Micro-LED, and has received extensive attention and research. Mini-LED has good display effect and lightness, and has advantages of high contrast and long life. People are constantly optimizing its design, and trying to design products with better performance.

### SUMMARY

At least one embodiment of the present disclosure provides a light-emitting substrate, a backlight module and a display device.

At least one embodiment of the present disclosure provides a light-emitting substrate, which includes a base substrate, a plurality of first drive units and a second drive unit, the plurality of first drive units are located on the base substrate, the plurality of first drive units are arranged in an array in a first direction and a second direction, each of the plurality of first drive units includes a plurality of first connection portions, the first direction and the second direction are both parallel to the base substrate, and the first direction intersects with the second direction; the second drive unit is located on the base substrate, the second drive unit includes a second connection portion and a plurality of first leads electrically connected to the second connection portion, at least a portion of the second drive unit is located between two first drive units adjacent in the first direction, and between two first drive units adjacent in the second direction, and at least one first lead includes a test pad, the test pad is configured to detect a signal in the first lead.

For example, according to the array substrate provided by at least one embodiment of the present disclosure, the light-emitting substrate further includes a plurality of first signal lines electrically connected to the second connection portion, an orthographic projection, on the base substrate, of the test pad does not overlap with an orthographic projection, on the base substrate, of each of the plurality of first signal lines.

For example, according to the array substrate provided by at least one embodiment of the present disclosure, the first connection portion and the first drive unit are distributed in a staggered manner in the first direction, and the first connection portion and the first drive unit are distributed in a staggered manner in the second direction.

For example, according to the array substrate provided by at least one embodiment of the present disclosure, in the first direction, end portions, away from the second connection portion, of the plurality of first leads in one second drive unit are all located on one side of the second connection portion, and an orthographic projection, on the base substrate, of the test pad in one first lead does not overlap with an orthographic projection, on the base substrate, of another adjacent first lead.

For example, according to the array substrate provided by at least one embodiment of the present disclosure, the test pad in one of the plurality of first leads does not overlap with the second connection portion in the first direction, and/or the test pad of another one of the plurality of first leads at least partially overlaps with the second connection portion in the first direction, and is located in a spacing between two first drive units adjacent in the second direction.

For example, according to the array substrate provided by at least one embodiment of the present disclosure, the plurality of first signal lines extend in the second direction and include a first conductive line, a second conductive line, a third conductive line, and a fourth conductive line; and the second connection portion includes a first connection end, a second connection end, a third connection end and a fourth connection end, and the plurality of first leads include a first connection line, a second connection line, a third connection line and a fourth connection line, the first connection end is electrically connected to the first conductive line through the first connection line, the second connection end is electrically connected to the second conductive line through the second connection line, the third connection end is electrically connected to the third conductive line through the third connection line, and the fourth connection end is electrically connected to the fourth conductive line through the fourth connection line.

For example, according to the array substrate provided by at least one embodiment of the present disclosure, at least one selected from a group consisting of the first connection line, the second connection line, and the third connection line includes the test pad.

For example, according to the array substrate provided by at least one embodiment of the present disclosure, in the second drive unit, the first connection end and the second connection end are adjacently provided in the first direction, and the first connection end is closer to the first conductive line adjacent to the second drive unit than the second connection end, and the first connection line is located between two first drive units adjacent in the second direction, and an end portion, away from the second drive unit, of the first connection line includes a first test pad, the first test pad is configured to detect an input signal, an end, away from the second drive unit, of the second connection line includes a second test pad, the second test pad is configured to detect an output signal, and in the second direction, the first test pad and the second test pad are respectively located on two sides of the same one first connection portion.

For example, according to the array substrate provided by at least one embodiment of the present disclosure, in the second direction, an end portion, away from the second connection portion, of the third connection line and an end portion, away from the second connection portion, of the fourth connection line are both located on one side, away from the first connection line adjacent to one first connection portion, of the same one first connection portion.

For example, according to the array substrate provided by at least one embodiment of the present disclosure, in the second direction, the third connection line and the fourth connection line are both located between the first test pad and the second test pad.

For example, according to the array substrate provided by at least one embodiment of the present disclosure, the third connection line includes a first integration portion, the fourth connection line includes a second integration portion, the first integration portion is configured to be electrically connected to one end of a capacitor, and the second integration portion is configured to be electrically connected to the other end of the capacitor, and in the first direction, the first integration portion and the second integration portion are both located between a portion, extending in the second direction, of the second connection line and the second conductive line electrically connected to the second connection line.

For example, according to the array substrate provided by at least one embodiment of the present disclosure, the second drive unit and the first drive unit are distributed in a staggered manner in the first direction.

For example, according to the array substrate provided by at least one embodiment of the present disclosure, a center of an orthographic projection, on the base substrate, of the second connection portion substantially coincides with a center of a pattern enclosed by connection lines of centers of orthographic projections, on the base substrate, of adjacent four first connection portions.

For example, according to the array substrate provided by at least one embodiment of the present disclosure, in the second drive unit, the first connection end and the second connection end are adjacently provided in the second direction, and the third connection end and the fourth connection end are adjacently provided in the second direction, and an end portion, away from the second drive unit, of the first connection line includes a first test pad, an end portion, away from the second drive unit, of the second connection line includes a second test pad, and in the second direction, the first test pad and the second test pad are located on one side of the same one first connection portion.

For example, according to the array substrate provided by at least one embodiment of the present disclosure, the first connection line, the second connection line, and the third connection line are all located between two first drive units adjacent in the second direction.

For example, according to the array substrate provided by at least one embodiment of the present disclosure, in the second direction, the third connection line is located on one side, away from the first connection line, of the second connection line; and in the first direction, at least a portion of the fourth connection line is located on one side, away from the first conductive line, of the first connection line.

For example, according to the array substrate provided by at least one embodiment of the present disclosure, the first drive unit includes a plurality of first drive portions, and each of the plurality of first drive portions includes a plurality of the first connection portions sequentially connected in series, and the first drive unit includes a drive connection portion, the plurality of first drive portions are arranged in an array in the first direction and the second direction, and the drive connection portion is located in a region enclosed by connection lines of centers of some of the plurality of the first connection portions adjacent to the drive connection portion.

For example, according to the array substrate provided by at least one embodiment of the present disclosure, the plurality of first drive portions include a first drive sub-portion, a second drive sub-portion, a third drive sub-portion, and a fourth drive sub-portion arranged in two rows and two columns, and the drive connection portion is located in a region enclosed by connection lines of centers of four first connection portions adjacent to the drive connection portion.

For example, according to the array substrate provided by at least one embodiment of the present disclosure, the light-emitting substrate further includes a plurality of second signal lines, the first drive portion is electrically connected to the plurality of second signal lines, and at least one of the plurality of second signal lines is located between the first drive sub-portion and the second drive sub-portion adjacent in the first direction, and is located between the third drive sub-portion and the fourth drive sub-portion adjacent in the first direction.

For example, according to the array substrate provided by at least one embodiment of the present disclosure, in the second direction, at least two first drive portions are provided between two second connection portions which are located in one same column and adjacent to each other.

For example, according to the array substrate provided by at least one embodiment of the present disclosure, in the second direction, one end, away from the second connection end, of the second connection line of one second drive unit is electrically connected to one end, away from the first connection end, of the first connection line of another adjacent second drive unit, and the light-emitting substrate further includes a bonding region, and, in a plurality of the second drive units in one same column, the first connection line of a first one of the plurality of the second drive units is electrically connected to one end of one first conductive line, and the other end of the one first conductive line is connected to the bonding region, and one end of the second connection line of a last one of the plurality of the second drive units is electrically connected to one end of one second conductive line, and the other end of the one second conductive line is connected to the bonding region.

At least one embodiment of the present disclosure provides a backlight module, which includes the light-emitting substrate according to any one of the above embodiments.

At least one embodiment of the present disclosure provides a display device, which includes the backlight module according to any one of the above embodiment.

### BRIEF DESCRIPTION OF DRAWINGS

In order to more clearly illustrate the technical solutions of the embodiments of the present disclosure, the accompanying drawings of the embodiments will be briefly described below, and it will be apparent that the accompanying drawings in the following description relate only to some of the embodiments of the present disclosure and are not a limitation of the present disclosure.

FIG. 1 is a partial structural schematic diagram of a light-emitting substrate according to at least one embodiment of the present disclosure.

FIG. 2 is a partial schematic cross-sectional diagram of a light-emitting substrate according to at least one embodiment of the present disclosure.

FIG. 3A is a partially enlarged schematic diagram corresponding to the light-emitting substrate in FIG. 1.

FIG. 3B is an enlarged schematic diagram corresponding to a second drive unit in FIG. 1.

FIG. 4 is a planar schematic diagram corresponding to a first conductive layer in FIG. 1.

FIG. 5 is a partial structural schematic diagram corresponding to a drive connection portion in FIG. 1.

FIG. 6 is a connection schematic diagram of a second drive unit of a light-emitting substrate according to at least one embodiment of the present disclosure.

FIG. 7 is an overall structural schematic diagram of a light-emitting substrate according to at least one embodiment of the present disclosure.

FIG. 8 is a partial planar schematic diagram corresponding to the first conductive layer in FIG. 6.

FIG. 9 is a structural arrangement schematic diagram of a light-emitting substrate according to at least one embodiment of the present disclosure.

FIG. 10 is a structural schematic diagram of another light-emitting substrate according to at least one embodiment of the present disclosure.

FIG. 11 is a connection schematic diagram of a second drive unit of another light-emitting substrate according to at least one embodiment of the present disclosure.

FIG. 12 is a schematic diagram of a display device according to at least one embodiment of the present disclosure.

### DETAILED DESCRIPTION

In order to make the purpose, technical solutions and advantages of the embodiments of the present disclosure clearer, the technical solutions of the embodiments of the present disclosure will be described clearly and completely in the following in conjunction with the accompanying drawings of the embodiments of the present disclosure. Obviously, the described embodiments are a part of the embodiments of the present disclosure, and not all of the embodiments. Based on the described embodiments of the present disclosure, all other embodiments obtained by a person of ordinary skill in the art without the need for creative labor fall within the scope of protection of the present disclosure.

Unless otherwise defined, technical or scientific terms used in the present disclosure shall have the ordinary meaning understood by a person of ordinary skill in the art to which the present disclosure belongs. The terms “first”, “second”, and the like as used in the present disclosure do not indicate any order, number, or significance, but are only used to distinguish different components. Words such as “including” or “comprising” and the like are intended to mean that the component or object preceded by the word encompasses the component or object enumerated after the word and its equivalents, and does not exclude other components or objects.

Features such as “perpendicular”, “parallel”, and “the same” as used in embodiments of the present disclosure include “perpendicular”, “parallel”, and “identical” in the strict sense, as well as “substantially perpendicular”, “substantially parallel”, “approximately the same”, etc. that include a certain amount of error, taking into account the measurement and the error associated with the measurement of the particular quantity (i.e., the limitations of the measurement system), which indicates being within a range of acceptable deviations for the particular value as determined by a person of ordinary skill in the art. “Center” in embodiments of the present disclosure may include a location strictly at the geometric center as well as a location approximately at the center within a small area around the geometric center.

In general, a light-emitting substrate as a backlight of a Mini-LED display device may include a first drive unit for driving a light-emitting element and a second drive unit for driving a sensor, the light-emitting element may be electrically connected to the first drive unit, and the sensor may be electrically connected to the second drive unit. For example, the sensor can detect light emission performance of the light-emitting element to facilitate monitoring the light emission of the backlight. At present, in a Mini-LED backlight design, the Mini-LED is mainly composed of a light-emitting element (e.g. a LED lamp) and a driving element IC (integrated circuit chip, IC chip). For example, the light-emitting element can be connected to a voltage signal line, a power source signal line, a common voltage signal line and a ground signal line, thereby achieving local dimming.

In a study, the inventors of the present disclosure found that: a large quantity of light-emitting elements in a backlight of a Mini-LED display device need to be driven separately, and first drive units and second drive units are both provided on a baes substrate in a large quantities; therefore, how to rationally arrange a large quantity of dense first drive units and second drive units on the base substrate, so as to enable the light-emitting substrate to have good performance becomes a current research difficulty. For example, in some design schemes, the first drive unit and the second drive unit may be arranged in one same row, or in one same column, and the first drive unit and the second drive unit are electrically connected to different signal lines, respectively, but such an arrangement may cause a problem in that the design space of the first drive unit and the second drive unit in the one same row is narrow, so that the first drive unit and the second drive unit in the row are closer to the signal lines, and signal crosstalk or poor signal transmission may easily occur. On the other hand, because Mini-LED has more light-emitting sources compared with a conventional direct-type backlight source or a side-in-type backlight source, the heat generation phenomenon is very serious, especially for a product with a high brightness requirement. The peak value of the brightness thereof may reach 4000 nit, and thus the heat generation phenomenon is very obvious. It is necessary to drive the sensor through the second drive unit to monitor the temperature of the whole light-emitting substrate, and upon the transmission signal of the sensor being abnormal during the process of monitoring the temperature of the light-emitting substrate (for example, upon the sensor having a poor welding such as a virtual welding), it is usually necessary to detect the second drive unit to which the sensor is connected. For example, the signal transmission state of a signal line electrically connected to the second drive unit is detected, so as to accurately identify the location where the failure occurs, and therefore, how to accurately detect the transmission signal of the sensor becomes a technical problem that needs to be overcome.

At least one embodiment of the present disclosure provides a light-emitting substrate, which includes a base substrate, a plurality of first drive units and a second drive unit, the plurality of first drive units are located on the base substrate, the plurality of first drive units are arranged in an array in a first direction and a second direction, one of the plurality of first drive units includes a plurality of first connection portions, the first direction and the second direction are both parallel to the base substrate, and the first direction intersects with the second direction; the second drive unit is located on the base substrate, the second drive unit includes a second connection portion and a plurality of first leads electrically connected to the second connection portion, at least a portion of the second drive unit is located between two first drive units adjacent in the first direction, and between two first drive units adjacent in the second direction, and at least one first lead includes a test pad, the test pad is configured to detect a signal in the first lead.

The embodiments of the present disclosure can detect a signal transmission state and accurately identify a failed sensor by providing the test pad in the first lead, which is advantageous in improving signal failure processing efficiency; at the same time, by optimizing the arrangement positions of the second drive units in the light-emitting substrate, it is possible to make the plurality of first leads connected to the second connection portion have sufficient wiring space, and have a reasonable arrangement manner, thereby reducing the risk of touching other signal lines and causing signal failure or inaccurate detection in the process of signal detection by the test pad.

Below, the display substrate and the method for manufacturing thereof, and the display device provided in the embodiments of the present disclosure will be described in conjunction with the accompanying drawings.

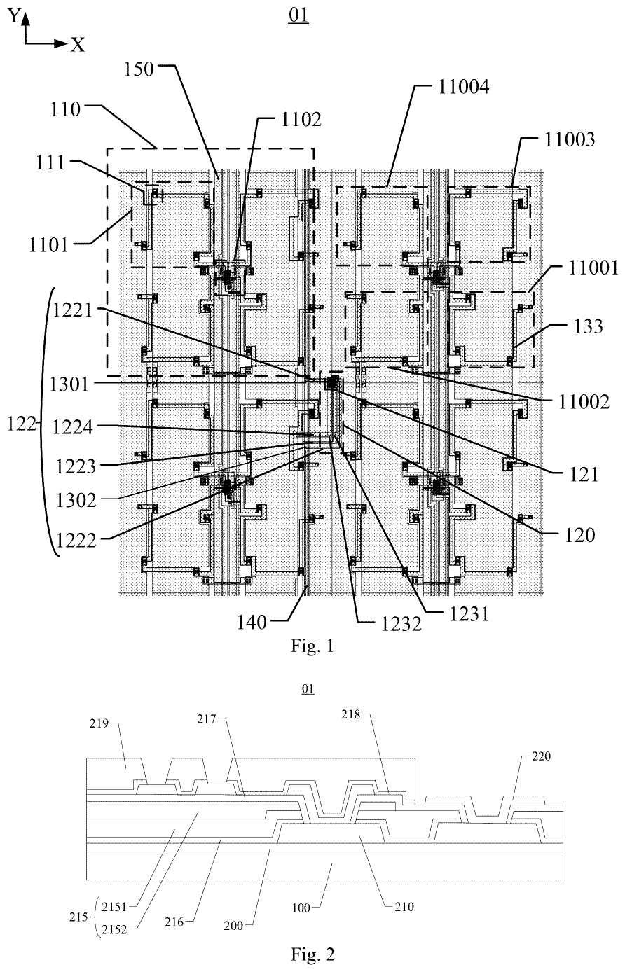

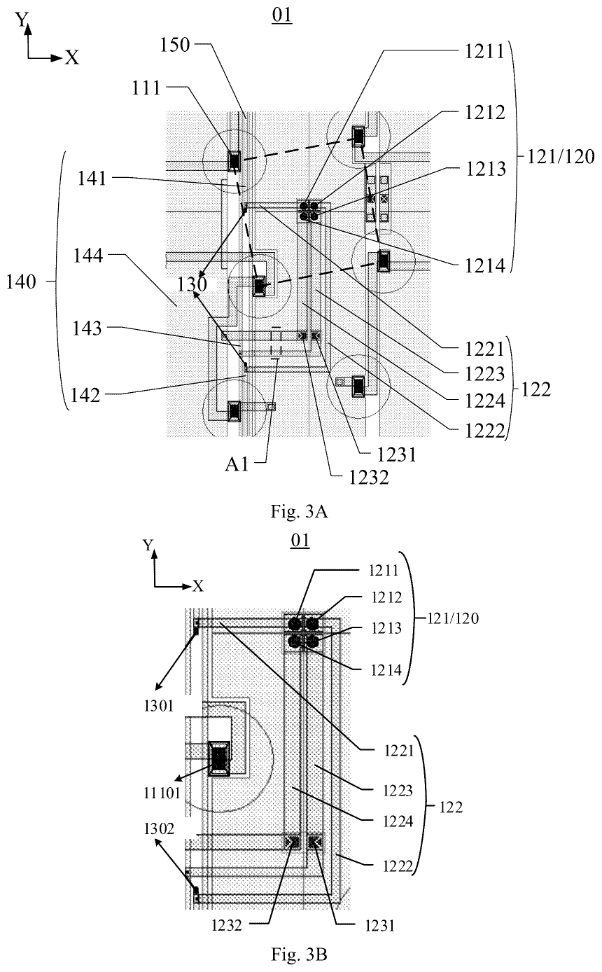

FIG. 1 is a partial structural schematic diagram of a light-emitting substrate according to at least one embodiment of the present disclosure. FIG. 2 is a partial schematic cross-sectional diagram of a light-emitting substrate according to at least one embodiment of the present disclosure. FIG. 3A is a partially enlarged schematic diagram corresponding to the light-emitting substrate in FIG. 1. FIG. 3B is an enlarged schematic diagram corresponding to a second drive unit in FIG. 1.

As shown in FIG. 1 and FIG. 2, the light-emitting substrate 01 includes a base substrate 100, a plurality of first drive units 110 and a second drive unit 120, the plurality of first drive units 110 and the second drive unit 120 are all located on the base substrate 100. As shown in FIG. 2, the light-emitting substrate 01 includes a first conductive layer 210 and a second conductive layer 220 sequentially provided in a direction perpendicular to the base substrate 100 and a first insulation layer 215 located between the first conductive layer 210 and the second conductive layer 220. For example, a plurality of first signal lines 140 electrically connected to the second drive unit 120 and second signal lines 150 electrically connected to the first drive unit 110 are provided in the first conductive layer 210.

For example, as shown in FIG. 2, a buffer layer 200 is further provided between the base substrate 100 and the first conductive layer 210 in the direction perpendicular to the base substrate 100 to remove local stress and improve adhesion. For example, a material of the buffer layer 200 may be silicon nitride, but is not limited thereto. For example, in some embodiments, upon the first signal line 140 and the second signal line 150 in the first conductive layer 210 being fabricated using an electroplating process, no buffer layer may be provided between the base substrate 100 and the first conductive layer 210. For example, a thickness of the first signal line 140 and a thickness of the second signal line 150 may be 1.5 μm to 7 μm. For example, a main material of the first signal line 140 and the second signal line 150 may be copper, but is not limited thereto. For example, the first signal line 140 and the second signal line 150 may also use a stack material of MoNb/Cu/MoNb. For example, MoNb close to the base substrate 100 may be used to improve adhesion, and MoNb away from the base substrate 100 may be used to reduce the risk of oxidation, but it is not limited thereto. For example, the first signal line 140 and the second signal line 150 may be made of different materials, which may be set according to design requirements. For example, the first signal line 140 and the second signal line 150 may be formed using an electroplating process, and the embodiments of the present disclosure are not limited thereto.

For example, as shown in FIG. 2, a second insulation layer 216 is further provided between the buffer layer 200 and the first insulation layer 215, and a third insulation layer 217 is further provided on one side, away from the base substrate 100, of the first insulation layer 215. For example, the second insulation layer 216 and the third insulation layer 217 may adopt the same material, such as, but not limited to, silicon nitride. For example, the second insulation layer 216 and the third insulation layer 217 may reduce the risk of oxidation of the signal lines. For example, as shown in FIG. 2, the first insulation layer 215 may include a first insulation sub-layer 2151 and a second insulation sub-layer 2152, and the first insulation sub-layer 2151 is closer to the base substrate 100 than the second insulation sub-layer 2152.

For example, as shown in FIG. 2, a fourth insulation layer 218 and a fifth insulation layer 219 are provided on one side, away from the base substrate 100, of the second conductive layer 220. For example, the fourth insulation layer 218 may be of the same material as the third insulation layer 217, such as, but not limited to, silicon nitride. For example, a thickness of the fifth insulation layer 219 may be greater than a thickness of the first insulation layer 215. For example, a thickness of the first insulation layer 215 may be 1.5 μm to 7 μm, and a thickness of the fifth insulation layer 219 may be greater than 3 μm, but it is not limited thereto. For example, the first insulation layer 215 and the fifth insulation layer 219 may be formed by a coating process, but are not limited thereto.

For example, as shown in FIG. 1 and FIG. 2, a plurality of first drive units 110 are arranged in an array in the first direction X and the second direction Y, the first drive unit 110 include a plurality of first connection portions 111, and the second drive unit 120 includes a second connection portion 121 and a plurality of first leads 122 electrically connected to the second connection portion 121. The first connection portion 111 in the first drive unit 110 and the first lead 122 and the second connection portion 121 in the second drive unit 120 are located at the second conductive layer. For example, the first connection portion 111 may be electrically connected to the light-emitting element to transmit a signal to the light-emitting element to drive the light-emitting element to emit light. For example, the light-emitting element includes a light-emitting diode. Further, for example, the light-emitting element includes Mini-LED or Micro-LED. For example, each first drive unit 110 may include a plurality of first connection portions 111 to simultaneously drive a plurality of light-emitting elements to emit light. For example, the plurality of first drive units 110 in the light-emitting substrate 01 may include different quantities of first connection portions 111 to accommodate an arrangement of the layout and different light-emitting requirements, but it is not limited thereto. For example, the first drive unit 110 may include a plurality of first drive portions 1101 and a drive connection portion 1102, and the first drive portion 1101 includes a plurality of first connection portions 111 sequentially connected in series, and the drive connection portion 1102 may be configured to transmit a driving signal to the first drive portions 1101 so that the first drive portions drive the light-emitting elements to emit light.

As shown in FIG. 1 and FIG. 2, at least a portion of the second drive unit 120 is located between two first drive units 110 adjacent in the first direction X and between two first drive units 110 adjacent in the second direction Y.

As shown in FIG. 1 and FIG. 2, an orthographic projection, on the base substrate 100, of the first drive unit 110 does not overlap with an orthographic projection, on the base substrate 100, of the second drive unit 120 to reduce signal interference with each other and facilitate signal control. With such an arrangement, at least a portion of the second drive unit 120 can be staggered with the plurality of first drive units 110 in the first direction X, and can be staggered with the plurality of first drive units 110 in the second direction Y, whereby the first drive units 110 in the same row in the first direction X and the first drive units 110 in the same column in the second direction Y have enough arrangement space, so that the wiring modes are more reasonable and orderly.

As shown in FIG. 3A and FIG. 3B, in the second drive unit 120, at least one first lead 122 includes a test pad 130, the test pad 130 is configured to detect a signal in the first lead 122. For example, the second connection portion 121 is electrically connected to the second signal line 150 through the first lead 122 to drive a sensor electrically connected thereto to perform temperature detection. For example, the test pad 130 located on the first lead 122 can detect the signal in the first lead 122, so that it can determine whether the signal transmission state of the sensor is normal. For example, the plurality of first leads 122 electrically connected to one same second connection portion 121 may be respectively configured to transmit different signals, and thus the test pads 130 located on the different first leads 122 are configured to detect the different signals, but it is not limited thereto. For example, both the first lead 122 and the test pad 130 are made of an conductive material. For example, a stack of MoNb/Cu/MoNb may be used, but it is not limited to. For example, the material of first lead 122 and the material of test pad 130 may be the same or may be different, and embodiments of the present disclosure are not limited in this respect.

For example, as shown in FIG. 1 and FIG. 3A, in at least one embodiment of the present disclosure, at least a portion of the above-mentioned second drive unit 120 may be a second connection portion 121 in the second drive unit 120, namely, the second connection portion 121 and the first drive unit 110 are distributed in a staggered manner in the first direction X, and the second connection portion 121 is distributed staggered with the first drive unit 110 in the second direction Y, such that the second connection portion 121 can be prevented from occupying too much arrangement space, such that the arrangement positions of the first drive unit 110 and the second drive unit 120 in the light-emitting substrate 01 are appropriate, and the utilization of layout space is more reasonable.

For example, as shown in FIG. 1 and FIG. 3A, in some embodiments, at least a portion of the second drive unit 120 described above may also be the second connection portion 121 and a portion of the first lead 122, and the second connection portion 121 and the portion of the first lead 122 are both located between two first drive units 110 adjacent in the first direction X and between two first drive units 110 adjacent in the second direction Y.

For example, in other embodiments, different from the light-emitting substrate shown in FIG. 1, at least a portion of the second drive unit 120 may also be a second connection portion 121 and at least one first lead 122 electrically connected thereto, such that the second connection portion 121 and the at least one first lead 122 are both located between two first drive units 110 adjacent in the first direction X and between two first drive units 110 adjacent in the second direction Y. That is, the second connection portion 121 and the at least one first lead 122 electrically connected thereto, in the second drive unit 120 of the light-emitting substrate 01 shown in FIG. 1, are located between two first drive units 110 adjacent in the first direction X and between two first drive units 110 adjacent in the second direction Y.

For example, in other embodiments, different from the light-emitting substrate shown in FIG. 1, at least a portion of the second drive unit 120 may also be the second connection portion 121 and all the first leads 122 electrically connected thereto, which is set according to the layout arrangement, and the embodiments of the present disclosure do not limit this. That is, the second connection portion 121 and all the first leads 122 electrically connected thereto, in the second drive unit 120 in the light-emitting substrate 01 shown in FIG. 1, are located between two first drive units 110 adjacent in the first direction X and between two first drive units 110 adjacent in the second direction Y, but are not limited thereto.

For example, as shown in FIG. 1, the first direction X and the second direction Y are both parallel to the base substrate 100, and the first direction X intersects with the second direction Y. For example, the first direction X may be perpendicular to the second direction Y, but is not limited thereto.

As shown in FIG. 1 and FIG. 2, the embodiments of the present disclosure can detect a signal transmission state and accurately identify a failed sensor by providing the test pad 130 in the first lead 122, and, at the same time, by optimizing the arrangement positions of the second drive units 120 in the light-emitting substrate 01, it is possible to make a plurality of first leads 122 connected to the second connection portion 121 have sufficient wiring space and have a reasonable arrangement manner, thereby reducing the risk of touching other signal lines and causing signal failure or inaccurate detection in the process of signal detection by the test pad 130.

For example, as shown in FIG. 2 and FIG. 3A, the orthographic projection, on the base substrate 100, of the test pad 130 does not overlap with an orthographic projection, on the base substrate 100, of the first signal lines 140. For example, the first signal line 140 not electrically connected with the test pad 130 are spaced from the test pad 130 in the first direction X. For example, the test pad 130 extends in the same direction as the first signal line 140 adjacent thereto, but it is not limited thereto. With such an arrangement, upon the test pad 130 being tested, for example, upon it being electrically connected to the test pad 130 by a “pin prick test”, it is possible to reduce the risk of touching other signal lines, such as the first signal line 140, reducing the risk of errors in the detecting signal, thereby improving the accuracy upon testing being made against the test pad 130.

For example, as shown in FIG. 3A, in the first direction X, ends, away from the second connection portion 121, of the plurality of first leads 122 within one same second drive unit 120 are both located on one same side of the second connection portion 121, that is, the plurality of first signal lines 140 electrically connected to the second drive unit 120 are located on one same side of the second drive unit 120, thereby facilitating a connection of each of the plurality of first signal lines 140 and a control of the plurality of first signal lines 140, but the embodiments of the present disclosure are not limited thereto.

For example, as shown in FIG. 3A, the orthographic projection, on the base substrate 100, of the test pad 130 in one first lead 122 does not overlap with the orthographic projection, on the base substrate 100, of another adjacent first lead 122. For example, the plurality of first leads 122 includes a first connection line 1221, a second connection line 1222, a third connection line 1223, and a fourth connection line 1224, and the plurality of first leads 122 are electrically connected to one same second connection portion 121. The first connection line 1221 extends in the first direction X, and the second connection line 1222, the third connection line 1223, and the fourth connection line 1224 each include a portion extending in the first direction X and another portion extending in a second direction Y, and in the second direction Y, the first connection line 1221, the second connection line 1222, the third connection line 1223, and the fourth connection line 1224 are provided at intervals. For example, the test pads 130 in the first connection line 1221, the second connection line 1222, the third connection line 1223, and the fourth connection line 1224 may be located at their ends away from the second connection portion 121, respectively. For example, the test pad 130 may be positioned between two first signal lines 140 adjacent in the first direction X such that the test pad 130 in one first lead 122 is spaced apart from another first signal line 140 in the second direction Y.

For example, as shown in FIG. 3A, an end, away from the second connection portion 121, of the first connection line 1221 and an end, away from the second connection portion 121, of the second connection line 1222 each include a test pad 130, and the test pad 130 in the first connection line 1221 is spaced apart from any one of the second connection line 1222, the third connection line 1223, and the fourth connection line 1224 in the second direction Y without overlapping. The test pad 130 in the second connection line 1222 is spaced apart from any one of the first connection line 1221, the third connection line 1223, and the fourth connection line 1224 in the second direction Y without overlapping. By providing no overlap between the orthographic projection, on the base substrate 100, of the test pad 130 in one first lead 122 and the orthographic projection, on the base substrate 100, of another adjacent first lead 122, the risk of touching other first leads 122 can be reduced while contact detection of the test pad 130 is performed, which can improves the accuracy of signal detection.

For example, as shown in FIG. 3A, the test pad 130 in one of the first leads 122 does not overlap with the second connection portion 121 in the first direction X. For example, the test pad 130 in any one selected from a group consisting of the second connection line 1222, the third connection line 1223, and the fourth connection line 1224 does not overlap with the second connection portion 121 in the first direction X.

For example, as shown in FIG. 1 and FIG. 3A, the test pad 130 of another one of the plurality of first leads 122 at least partially overlaps with the second connection portion 121 in the first direction X and is located in a spacing between two first drive units 110 adjacent in the second direction Y. For example, the test pad 130 in the first connection line 1221 at least partially overlaps with the second connection portion 121 in the first direction X, and the first connection line 1221 is located between two first drive units 110 adjacent in the second direction Y, such that the test pad 130 in the first connection line 1221 is spaced apart from the two first drive units 110 adjacent in the second direction Y, such that it is possible to reduce the risk of being electrically connected to the first drive units 110 while performing signal detection through the test pad 130, and the risk of interfering with normal driving of the first drive units 110 can be reduced.

For example, as shown in FIG. 3A, the plurality of first signal lines 140 extend in the second direction Y, and include a first conductive line 141, a second conductive line 142, a third conductive line 143, and a fourth conductive line 144. For example, the first conductive line 141, the second conductive line 142, the third conductive line 143, and the fourth conductive line 144 are provided at intervals in the first direction X, but are not limited thereto. For example, the second connection portion 121 includes a first connection end 1211, a second connection end 1212, a third connection end 1213, and a fourth connection end 1214, the first connection end 1211 is electrically connected to the first conductive line 141 through the first connection line 1221, the second connection end 1212 is electrically connected to the second conductive line 142 through the second connection line 1222, the third connection end 1213 is electrically connected to the third conductive line 143 through the third connection line 1223, and the fourth connection end 1214 is electrically connected to the fourth conductive line 144 through the fourth connection line 1224. For example, the plurality of first signal lines 140 may be configured to transmit different signals to the second connection portion 121, and than to be electrically connected with the sensor. For example, the first conductive line 141 may be configured to transmit an input signal, the second conductive line 142 may be configured to transmit an output signal, the third conductive line 143 may be configured to transmit a power source signal, and the fourth conductive line 144 may be configured to transmit a common voltage signal, such as a ground signal, but it is not limited thereto.

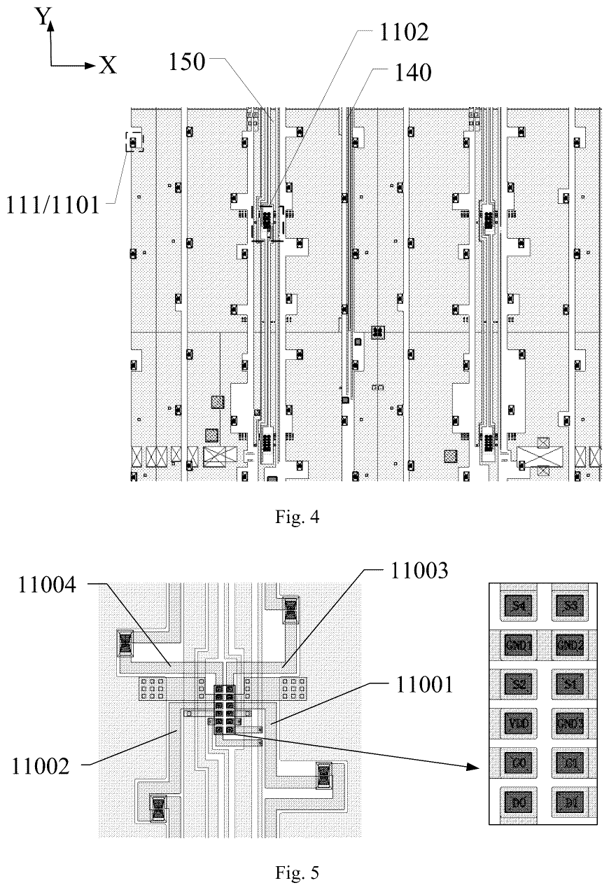

FIG. 4 is a planar schematic diagram corresponding to a first conductive layer in FIG. 1.

For example, as shown in FIG. 3A and FIG. 4, at least a portion of the first signal line 140 and at least a portion of the second signal line 150 are spaced apart in the first direction X, and an orthographic projection, on the substrate, of the first drive portion 1101 in the first drive unit 110 does not overlap with an orthographic projection, on the base substrate, of the drive connection portion 1102. Main portions of the first signal line 140 and the second signal line 150 both extend in the second direction Y, but it is not limited thereto.

For example, as shown in FIG. 3A, at least one selected from the group consisting of the first connection line 1221, the second connection line 1222, and the third connection line 1223 includes the test pad 130. For example, to detect different signals, the first connection line 1221 and the second connection line 1222 may each include the test pad 130 to facilitate detection of the input signal and the output signal, respectively, but it is not limited thereto. For example, the third connection line 1223 may also include the test pad 130 to facilitate detection of the transmission state of the power source signal, but it is not limited thereto.

For example, as shown in FIG. 3A, in the second drive unit 120, the first connection end 1211 and the second connection end 1212 are adjacently provided in the first direction X. For example, the first connection end 1211 and the second connection end 1212 may be located in the same row in the first direction X, and the first connection end 1211 is closer to the first conductive line 141 adjacent to the second drive unit 120 than the second connection end 1212, such that it is more advantageous for the first connection line 1221 connected to the first connection end 1211 to be connected to the first conductive line 141.

For example, as shown in FIG. 3A and FIG. 3B, the first connection line 1221 is located between two first drive units 110 adjacent in a second direction Y, an end portion, away from the second drive unit 120, of the first connection line 1221 includes a first test pad 1301 configured to detect an input signal, an end portion, away from the second drive unit 120, of the second connection line 1222 includes a second test pad 1302 configured to detect an output signal, and, in the second direction Y, the first test pad 1301 and the second test pad 1302 are respectively located on both sides of one same first connection portion 111 (e.g. the first connection portion 11101). Thus, the first test pad 1301 and the second test pad 1302 are spaced apart in the second direction Y, and are separated by the first connection portion 11101, which facilitates a reasonable use of the layout space on both sides of the first connection portion 11101, and reduces the risk of signal crosstalk upon both the input signal and the output signal being detected. As shown in FIG. 3A, the first connection portion 11101 is provided between the first connection line 1221 and the second connection line 1222, and the first test pad 1301 and the second test pad 1302 are respectively located on two sides of the same one first connection portion 11101. As shown in FIG. 3A, the first test pad 1301 is provided on an upper side of the first connection portion 11101 between the first connection line 1221 and the second connection line 1222, and the second test pad 1302 is provided on a lower side of the first connection portion 11101 between the first connection line 1221 and the second connection line 1222.

For example, as shown in FIG. 3A, in the second direction Y, an end portion, away from the second connection portion 121, of the third connection line 1223 and an end portion, away from the second connection portion 121, of the fourth connection line 1224 are both located on one side, away from the first connection line 1221 adjacent to the first connection portion 11101, of one same first connection portion 11101. For example, they may both be located on one side, close to the second connection line 1222 adjacent to the first connection portion 11101, of the first connection portion 11101, such that layout space located on the first connection line 1221 and the second connection line 1222 in the second direction Y can be reasonably utilized.

For example, as shown in FIG. 3A, in some embodiments, in the second direction Y, the end portion, away from the second connection portion 121, of the third connection line 1223 and the end portion, away from the second connection portion 121, of the fourth connection line 1224 may be located on the same side of one same first connection portion 11101 as the end portion, away from the second connection portion 121, of the second connection line 1222, and may be located on a different side of the one same first connection portion 11101 from the end portion, away from the second drive unit 120, of the first connection line 1221, which may be specifically set according to installation requirements, so as to rationally utilize layout space, and the embodiments of the present disclosure do not limit this.

For example, as shown in FIG. 1 and FIG. 3A, in the second direction Y, the third connection line 1223 and the fourth connection line 1224 are both located between the first test pad 1301 and the second test pad 1302, to rationally utilize the layout space between the first test pad 1301 and the second test pad 1302 in the second direction Y. For example, a portion, extending in the first direction X, of the third connection line 1223 and a portion, extending in the first direction X, of the fourth connection line 1224 are located between portions, extending in the first direction X, of the first connection line 1221 and the second connection line 1222, but it is not limited thereto. In the second direction Y, the first test pad 1301 is located on one side, away from the third connection line 1223, of the fourth connection line 1224, and the second test pad 1302 is located on one side, away from the fourth connection line 1224, of the third connection line 1223, but it is not limited thereto.

For example, as shown in FIG. 3A, the third connection line 1223 includes a first integration portion 1231, and the fourth connection line 1224 includes a second integration portion 1232, the first integration portion 1231 is configured to be electrically connected to one end of a capacitor, the second integration portion 1232 is configured to be electrically connected to the other end of the capacitor, such that the capacitor can be bonded to filter signal noise through the capacitor, making the transmission of the electrical signal between the sensor and the first signal line 140 more stable. For example, one pin of the capacitor is connected to the first integration portion 1231 and the other pin of the capacitor is connected to the second integration portion 1232.

For example, as shown in FIG. 3A, in the first direction X, the first integration portion 1231 and the second integration portion 1232 are both located between a portion, extending in the second direction, of the second connection line 1222 and the second conductive line 142 electrically connected to the second connection line 1222. For example, the first integration portion 1231 and the second integration portion 1232 are spaced apart and arranged side by side in the first direction X, and are located on one side, close to the second signal line 150, of a portion, extending in the second direction Y, of the second connection line 1222, but it is not limited thereto. For example, in response to the layout space between the portion, extending in the second direction Y, of the second connection line 1222 and the second signal line 150 being relatively loose, the first integration portion 1231 and the second integration portion 1232 may also be located in a region Al, and the first integration portion 1232 and the second integration portion 1232 may be spaced apart and arranged side by side in the second direction Y. For example, an orthographic projection, on the base substrate, of the first integration portion 1232 and an orthographic projection, on the base substrate, of the second integration portion 1232 do not overlap with an orthographic projection, on the base substrate, of the sensor, and do not overlap with an orthographic projection, on the base substrate, of the first drive unit 110 (as shown in FIG. 1), so as to reduce the risk of signal interference.

For example, as shown in FIG. 3A, a center of the orthographic projection, on the base substrate 100, of the second connection portion 121 substantially coincides with a center of a pattern enclosed by connection lines of centers of orthographic projections, on the base substrate 100 (shown in FIG. 2), of adjacent four first connection portions 111. For example, the center of the orthographic projection may be a center of symmetry of the projection, or the center of gravity. For example, the pattern enclosed by the connection lines of centers of the orthographic projections, on the base substrate 100, of the four first connection portions 111 adjacent to the second connection portion 121 may be a rectangle, such as a square, but it is not limited thereto. The distances between the second connection portion 121 and the adjacent four first connection portions 111 are substantially equal, such that the distances between the second connection portion 121 and the adjacent four first drive units 110 are substantially equal, such that the layout utilization space can be balanced, and the distances between the sensor and the adjacent plurality of light-emitting elements can be substantially the same, so as to facilitate temperature detection of each light-emitting element.

For example, as shown in FIG. 1 and FIG. 3A, in some embodiments of the present disclosure, the quantity of the plurality of first connection portions 111 adjacent to the second connection portion 121 is not limited to four, and may be specifically set according to the quantity and positions of the first connection portions 111 in the first drive portion 1101. For example, one same first drive portion 1101 may include two first connection portions 111 that are approximately equidistant from the second connection portion 121, such that the quantity of the plurality of first connection portions 111 adjacent to the second connection portion 121 may be eight, but it is not limited thereto.

For example, with reference to FIG. 1 and FIG. 3A, the distances between the first connection line 1221 and the adjacent two first drive units 110 are different. For example, in other embodiments, the distances between the first connection line 1221 and the two adjacent first drive units 110 may also be substantially the same in the second direction Y. For example, in the second direction Y, the two first drive units 110 adjacent to the first connection line 1221 may be two first drive units 110 located on both sides of the first connection line 1221, respectively, with the smallest distance from the first connection line 1221. With such an arrangement, the layout space in the second direction Y of the two first drive units 110 adjacent to the first connection line 1221 can be reasonably utilized, the risk with elements in the first driving unit 110 (for example, the first connecting portion 111) while signal detection is carried out through the first test pad 1301 (as shown in FIG. 1) can be reduced, so as to facilitate signal detection and control.

For example, as shown in FIG. 1, the plurality of first drive portions 1101 are arranged in an array in the first direction X and the second direction Y, and the drive connection portion 1102 is located in the region enclosed by the connection lines of the centers of some of the plurality of first connection portions 111 adjacent thereto. Taking the light-emitting substrate 01 shown in FIG. 1 as an example, the first drive unit 110 may include four first drive portions 1101, and the four first drive portions 1101 are arranged in two rows and two columns, and each first drive portion 1101 includes four first connection portions 111, but is not limited thereto.

For example, as shown in FIG. 1, adjacent first connection portions 111 are electrically connected through second leads 133, and the pattern enclosed by the connection lines of the centers of the orthographic projections, on the base substrate, of the plurality of first connection portions 111 in one same first drive portion 1101 is substantially rectangular, but it is not limited thereto. For example, the drive connection portion 1102 may include a driving circuit for driving the first drive portion 1101, and may, for example, include a driving chip. In the light-emitting substrate 01, each drive connection portion 1102 may be configured to drive a plurality of first drive portions 1101, which may effectively improve the driving efficiency, and help to save the layout area occupied by the drive connection portion 1102.

For example, as shown in FIG. 1, one drive connection portion 1102 may drive four first drive portions 1101 adjacent thereto at the same time, and the one drive connection portion 1102 can be located in the region enclosed by the connection lines of the centers of the orthographic projections, on the base substrate, of four first connection portions 111 located close to one another in the four first drive portions 1101. For example, the drive connection portion 1102 may be located approximately in the middle of the region to have substantially the same distance relative to the plurality of adjacent first connection portions 111.

For example, as shown in FIG. 1, the plurality of first drive portions 1101 may include a first drive sub-portion 11001, a second drive sub-portion 11002, a third drive sub-portion 11003, and a fourth drive sub-portion 11004 arranged in two rows and two columns, and the drive connection portion 1102 is located in a region enclosed by connection lines of centers of four first connection portions 111 adjacent thereto, that is, the drive connection portion 1102 is located in a region enclosed by connection lines of centers of the four first connection portions 111 close to one another in the first drive sub-portion 11001, the second drive sub-portion 11002, the third drive sub-portion 11003, and the fourth drive sub-portion 11004. For example, the orthographic projection, on the base substrate, of the drive connection portion 1102 does not overlap with the orthographic projections, on the base substrate, of the first connection portions 111 in the first drive sub-portion 11001, the second drive sub-portion 11002, the third drive sub-portion 11003, and the fourth drive sub-portion 11004.

For example, as shown in FIG. 1, with such an arrangement, it is possible to simplify the structure of the first drive unit 110, reduce the quantity of elements in the first drive unit 110, so as to facilitate the simultaneous control of the plurality of first drive portions 1101 by the drive connection portion 1102, and save the layout space.

For example, as shown in FIG. 1, the embodiments of the present disclosure do not limit the quantity of the plurality of first drive portions 1101 driven by the drive connection portion 1102, which may be specifically determined according to the quantity of the first drive portions 1101 in the first drive unit 110. For example, the drive connection portion 1102 may include a microchip, and a dimension (e.g. length) of the microchip may be on the order of tens or hundreds of micrometers, and an area of the chip may be on the order of tens of thousands of square micrometers or hundreds of square micrometers or even smaller, which has a miniaturization feature, so as to be integrated into the light-emitting substrate 01, but it is not limited thereto.

FIG. 5 is a partial structural schematic diagram corresponding to a drive connection portion in FIG. 1.

For example, as shown in FIG. 1 and FIG. 5, the first drive portion 1101 is electrically connected to a plurality of second signal lines 150, at least one second signal line 150 is located between the first drive sub-portion 11001 and the second drive sub-portion 11002 adjacent in the first direction X, and is between the third drive sub-portion 11003 and the fourth drive sub-portion 11004 adjacent in the first direction X. For example, the first drive portion 1101 may be electrically connected to the plurality of second signal lines 150 through the drive connection portion 1102, the drive connection portion 1102 may include a plurality of driving terminals, and a dimension of the drive connection portion 1102 in the first direction X is smaller than a dimension of the drive connection portion 1102 in the second direction Y, such that, in the first direction X, a layout occupation area of the drive connection portion 1102 between the first drive sub-portion 11001 and the second drive sub-portion 11002 can be reduced, and it is advantageous for the drive connection portion 1102 to be electrically connected to the plurality of second signal lines 150.

For example, as shown in FIG. 1 and FIG. 5, the drive connection portion 1102 may include twelve driving terminals. The first drive sub-portion 11001, the second drive sub-portion 11002, the third drive sub-portion 11003, and the fourth drive sub-portion 11004 are connected to four driving terminals, that is, a driving terminal S1, a driving terminal S2, a driving terminal S3, and a driving terminal S4, in the drive connection portion 1102 through corresponding conductive lines, and the remaining eight driving terminals are electrically connected to corresponding second signal lines 150 respectively, so as to transmit different driving signals. For example, the first drive sub-portion 11001 is electrically connected to the driving terminal S1, the second drive sub-portion 11002 is electrically connected to the driving terminal S2, the third drive sub-portion 11003 is electrically connected to the driving terminal S3, and the fourth drive sub-portion 11004 is electrically connected to the driving terminal S4. For example, the remaining eight driving terminals in the drive connection portion 1102 may include a first ground terminal GND1, a second ground terminal GND2, a third ground terminal GND3, a power source terminal VDD, a clock signal output terminal CO, a clock signal input terminal CI, a data signal output terminal DO, and a data signal input terminal DI, but are not limited thereto. For example, the first ground terminal GND1, the second ground terminal GND2 and the third ground terminal GND3 are respectively connected to a ground line, the power source terminal VDD is connected to a power source signal line, the clock signal input terminal CI is connected to a clock signal input line, the clock signal output terminal CO is connected to a clock signal output line, the data signal input terminal DI is connected to a data input signal line and the data signal output terminal DO is connected to a data output signal line.

For example, referring to FIG. 1, at least two first drive portions 1101 may be provided between two second connection portions 121 located in the same column and adjacent in the second direction Y. For example, the first connection portions 111 at corners in the same first drive portion 110 are respectively monitored by sensors connected to the second drive units 120 adjacent thereto. For example, the regions close to the four corners of the first drive portion 110 may be provided with sensors, respectively, but are not limited thereto. For example, the quantity of sensors may be set according to the monitoring performance and the monitoring demand. For example, in some embodiments, two or more first drive portions 110 may be provided at intervals between two adjacent second connection portions 121 in the same row. For example, for a plurality of second connection portions 121 in the same row, the second connection portion 121 has different distances from two adjacent second connection portions 121 thereto. For example, the quantities of the first drive portions 110 spaced between the second connection portion 121 and the second connection portion 121 on one side thereof is not equal to the quantity of the first drive portions 110 spaced between the second connection portions 121 and the second connection portion 121 on the other side thereof, but it is not limited thereto, and may be specifically set according to design requirements.

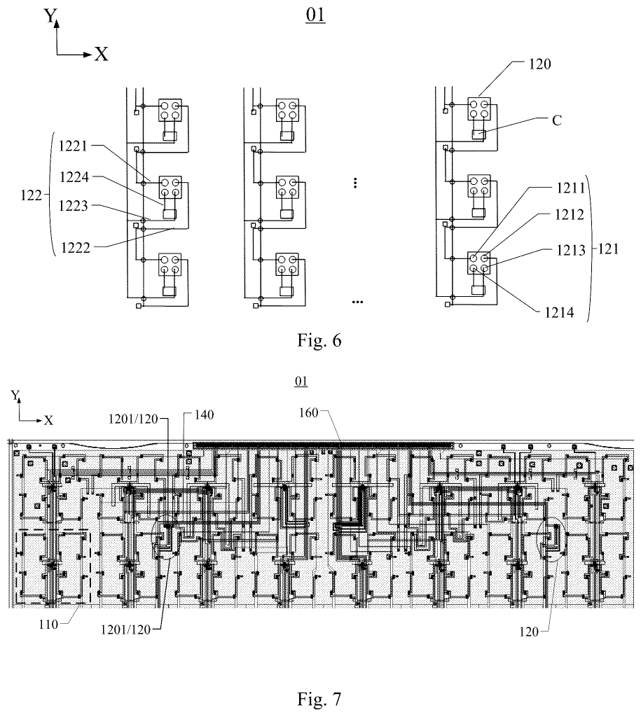

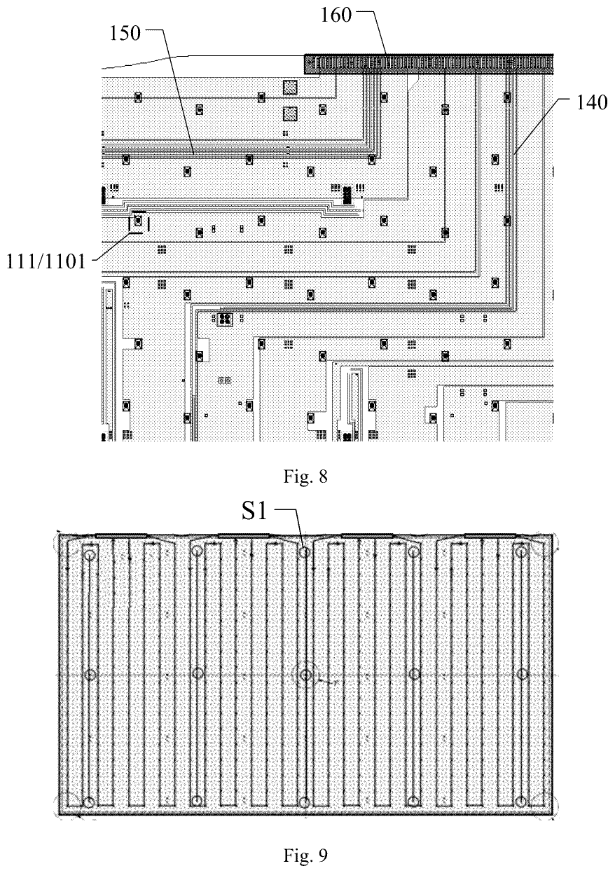

FIG. 6 is a connection schematic diagram of a second drive unit of a light-emitting substrate according to at least one embodiment of the present disclosure. FIG. 7 is an overall structural schematic diagram of a light-emitting substrate according to at least one embodiment of the present disclosure. FIG. 8 is a partial planar schematic diagram corresponding to the first conductive layer in FIG. 6. FIG. 9 is a structural arrangement schematic diagram of a light-emitting substrate according to at least one embodiment of the present disclosure.

For example, as shown in FIG. 3A and FIG. 6, in the second direction Y, an end, away from the second connection end 1212, of the second connection line 1222 of one second drive unit 120 is electrically connected to an end, away from the first connection end 1211, of the first connection line 1221 of another adjacent second drive unit 120, such that a plurality of second drive units 120 located in the same column can be connected in series. For example, the light-emitting substrate 01 further includes a bonding region 160 (see FIG. 7), and in the plurality of second drive units 120 in the same column, the first connection line 1221 of a first one of the second drive units 120 is electrically connected to one end of one first conductive line 141, and the other end of the one first conductive line 141 is connected to the bonding region, namely, the first conductive line 141 exits from the bonding region 160. One end of the second connection line 1222 of a last one of the second drive units 120 is electrically connected to one end of one second conductive line 142, and the other end of the one second conductive line 142 is connected to the bonding region 160, that is, the one second conductive line 142 is led back to the bonding region 160.

For example, as shown in FIG. 3A and FIG. 6, the third connection ends 1213 of the plurality of second drive units 120 located in the same column are all connected to one same third conductive line 143 through the third connection line 1223, and the plurality of fourth connection ends 1214 of the plurality of second drive units 120 located in the same column may be connected to one same fourth conductive line 144 through the fourth connection lines 1224, but it is not limited thereto. For example, FIG. 6 also shows a capacitor C electrically connected to the first integration portion 1231 and the second integration portion 1232 (see FIG. 3A).

For example, as shown in FIG. 7 and FIG. 8, a plurality of first drive units 110 in the light-emitting substrate 01 are arranged in an array on one side of the bonding region 160, one end of the first signal line 140 exits from the bonding region 160 and is electrically connected to a second drive unit 120, and one end of the second signal line 150 exits from the bonding region 160 and is electrically connected to the first drive unit 110. For example, the first signal line 140 and the second signal line 150 both exit from the bonding region 160 in the second direction Y, thereby extending to the first drive unit 110 or the second drive unit 120 to which electrical connection is required according to design requirements.

For example, as shown in FIG. 1, FIG. 3A, and FIG. 7, the first connection line 1221 of at least a portion of the second drive unit 120 (e.g. the second drive unit 1201) may also extend in the second direction Y, and thus be electrically connected to a portion, extending in the first direction Y, of the first signal line 140 adjacent thereto according to design requirements of the layout, thereby making the structural form of the second drive unit 1201 more flexible.

For example, as shown in FIG. 1 and FIG. 7, other structures may be designed in the light-emitting substrate 01 for better signal transmission according to design requirements, and the embodiments of the present disclosure do not limit this.

For example, as shown in FIG. 6 and FIG. 9, the quantity of the first conductive lines 141 in the light-emitting substrate 01 may be equal to the quantity of columns of the plurality of second drive units 120, such that the second drive units 120 in each column may be independently controlled. For example, upon an abnormality occurs in a signal transmitted by one of the sensors, it is possible to first locate the column in which the sensor is located, and the failed sensor may be quickly identified by detecting the test pad 130 in the first lead 122. The embodiments of the present disclosure effectively improve the ability to cope with the occurrence of a fault, facilitate signal transmission and device protection of the light-emitting substrate 01, and at the same time improve the sensor rework efficiency, by allowing the second drive units 120 of each column to be independently controlled and providing test pads 130 in the corresponding first leads 122 according to design requirements (for example, for each second drive unit 120, at least one first lead 122 electrically connected thereto includes the test pad 130), as compared to the manner in which a plurality of the second drive units 120 in the light-emitting substrate 01 are individually detected to determine whether the sensors are badly soldered, etc. For example, as shown in FIG. 9, the plurality of sensors S1 are arranged in the form of three rows and five columns, and the plurality of sensors S1 may be driven by columns, and the driving control between two adjacent columns of sensors may be independent from each other, but it is not limited thereto. For example, in some embodiments of the present disclosure, the plurality of sensors S1 may also be arranged in one of the arrangement of four rows and five columns and the arrangement of five rows and six columns, and the embodiments of the present disclosure are not limited to the arrangement of the plurality of sensors S1.

For example, as shown in FIG. 6, in some embodiments of the present disclosure, the quantities of second drive units 120 in two adjacent columns may be the same or different, and may be specifically set according to design requirements. For example, a quantity of the first conductive lines 141 in the light-emitting substrate 01 may be less than a quantity of columns of the second drive unit 120. For example, the second drive units 120 of two adjacent columns may be connected in series with each other according to the design requirements of the layout space. For example, the plurality of second drive units 120 located in one column are connected in series with one another, and the first connection line 1221 of the first one of the second drive units 120 in the plurality of second drive units 120 in the column is electrically connected to one end of one conductive line 141, and the other end of the one first conductive line 141 is connected to the bonding region (as shown in FIG. 7), one end of the second connection line 1222 of the last one of the second drive units 120 is electrically connected to one end of one second conductive line 142, and the other end of the one second conductive line 142 is connected to the first connection line 1221 to which the first one of the second drive units 120 in the plurality of second drive units 120 of another column is connected, but it is not limited thereto.

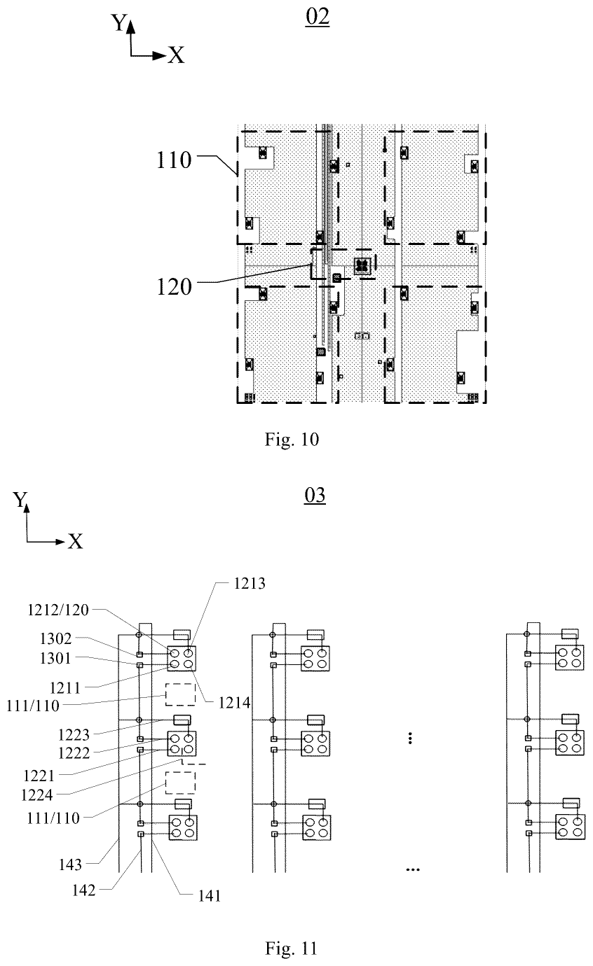

FIG. 10 is a structural schematic diagram of another light-emitting substrate according to at least one embodiment of the present disclosure.

For example, as shown in FIG. 10, in some embodiments of the present disclosure, in a light-emitting substrate 02, the second drive unit 120 and the first drive unit 110 are distributed in a staggered manner in the first direction X. For example, the second drive unit 120 does not overlap with the first drive unit 110 in the first direction X. For example, the plurality of second drive units 120 and the plurality of first drive units 110 are arranged alternately in the second direction Y. For example, compared to the light-emitting substrate 01 in FIG. 1, a structure of the first drive unit 110 of the light-emitting substrate 02 is substantially unchanged, and the first leads 122 of the second drive unit 120 of the light-emitting substrate 02 are each located between two first drive portions 110 adjacent in the second direction Y. For example, the first connection line 1221, the second connection line 1222, the third connection line 1223, and the fourth connection line 1224 in the plurality of first leads 122 are located between two first drive portions 110 adjacent in the second direction Y, such that it is possible to reduce an extension length of each first lead 122 in the second drive unit 120, and to reduce an adverse influence of the second drive unit 120 on the first drive unit 110 during driving.

For example, as shown in FIG. 10, the specific connection structure of the first drive unit 110 and the second drive unit 120 can be described with reference to FIG. 1 in the above-mentioned embodiment, and will not be repeated here.

FIG. 11 is a connection schematic diagram of a second drive unit of another light-emitting substrate according to at least one embodiment of the present disclosure.

For example, as shown in FIG. 11, in a light-emitting substrate 03, the first connection end 1211 and the second connection end 1212 of the second drive unit 120 are adjacently provided in the second direction Y, and the third connection end 1213 and the fourth connection end 1214 are adjacently provided in the second direction Y, compared to the connection manner of the second drive unit 120 in the light-emitting substrate 01 shown in FIG. 6. For example, the first connection end 1211, the second connection end 1212, the third connection end 1213 and the fourth connection end 1214 are arranged in an array of two rows and two columns in the first direction X and in the second direction Y. For example, an end portion, away from the second drive unit 120, of the first connection line 1221 includes a first test pad 1301, and an end portion, away from the second drive unit 120, of the second connection line 1222 includes a second test pad 1302. For example, the first test pad 1301 may test an input signal line in the first connection line 1221, and the second test pad 1302 may test an output signal in the second connection line 1222. For example, in the second direction Y, the first test pad 1301 and the second test pad 1302 may be located on one same side of one same first connection portion 111, thereby facilitating the detection of the first test pad 1301 and the second test pad 1302, and reducing the influence on other elements in the light-emitting substrate 03, such as the first drive unit 110.

For example, as shown in FIG. 11, the first connection line 1221, the second connection line 1222, and the third connection line 1223 may be located between two first drive units 110 adjacent in the second direction Y. For example, the fourth connection line 1224 is also located between the two first drive units 110 adjacent in the second direction Y, and the directions in which the third connection line 1223 and the fourth connection line 1224 extend in the first direction X are different. For example, the third connection line 1223 does not overlap with the fourth connection line 1224 in the second direction Y to reduce signal interference with each other, but are not limited thereto.

With such an arrangement, the layout space between the two first drive units 110 adjacent in the second direction Y can be effectively utilized and the signal transmission between the respective first leads 122 is facilitated.

For example, as shown in FIG. 11, in the second direction Y, the third connection line 1223 is located on one side, away from the first connection line 1221, of the second connection line 1222. For example, in the first direction X, at least a portion of the fourth connection line 1224 is located on one side, away from the first conductive line 141, of the first connection line 1221. Therefore, it is possible to make the third connection line 1223 and the fourth connection line 1224 provided outside the first connection line 1221 and the second connection line 1222, facilitate layout space arrangement, and facilitate signal transmission.

For example, as shown in FIG. 11, end portions, away from the second drive unit 120, of the third connection line 1223 and the fourth connection line 1224 may be provided with test pads, respectively, according to different signal detection requirements. For example, the first conductive line 141 may partially overlaps with the third conductive line 143, but does not have electrical connection to the third conductive line 143. In the first direction X, the second conductive line 142 is spaced between the first conductive line 141 and the third conductive line 143, and the fourth conductive line (not shown in the drawing) is located on one side, away from the third conductive line 143, of the second conductive line 142, but it is not limited thereto.

For example, as shown in FIG. 11, the specific connection structure of the first drive unit 110 and the second drive unit 120 can be described with reference to FIG. 1 in the above-mentioned embodiment, and will not be repeated here.

At least one embodiment of the present disclosure further provides a backlight module, which includes the light-emitting substrate (e.g. light-emitting substrate 01) described in any of the embodiments above, a plurality of light-emitting elements, and a plurality of sensors.

For example, as shown in FIG. 1, the sensor may be connected to the second connection portion 121. For example, the sensor may include four different pins and be connected to the first connection end 1211, the second connection end 1212, the third connection end 1213, and the fourth connection end 1214 of the second connection portion 121, respectively. For example, a quantity of pins in the sensor is the same as a quantity of the plurality of first signal lines 140. For example, the sensor is electrically connected to the plurality of first signal lines 140 in the light-emitting substrate 01 through the second connection portion, but it is not limited thereto.

For example, as shown in FIG. 1, the light-emitting element may be connected to the first connection portion 111. For example, the light-emitting element may include two pins having different polarities, e.g. a positive pin and a negative pin. The first connection portion 111 may include two corresponding connection ends having opposite polarities. For example, a positive connection end connected to the positive pin and a negative connection end connected to the negative pin. For example, in the first drive portion 1101, a quantity of light-emitting elements is the same as a quantity of the first connection portions 111. For example, the light-emitting element is electrically connected to the plurality of second signal lines 150 in the light-emitting substrate 01 through the first connection portion 111, but it is not limited thereto.

For example, the sensor can quickly and efficiently monitor the light emission of surrounding light-emitting elements, so as to timely adjust various parameters of the light-emitting elements, such as current, voltage brightness, so as to ensure stable performance of each light-emitting element. For example, the sensors may be of various types according to functions thereof, and for example, the sensor may be a temperature sensor to detect the temperature of the surrounding light-emitting elements so as to adjust parameters such as voltage and current to avoid a phenomenon such as desensitization of the system due to excessive temperature or line burn-out due to excessive voltage and current. For example, the sensor may be a photosensitive sensor to detect the brightness of surrounding light-emitting elements, to adjust the brightness of each light-emitting element in time such that the light-emitting elements emit light stably with a consistent brightness. For example, the sensor may also be an integrated sensor integrated on one chip and bound to the light-emitting substrate through the second connection portion 121, and embodiments of the present disclosure are not limited as to the type of sensors.

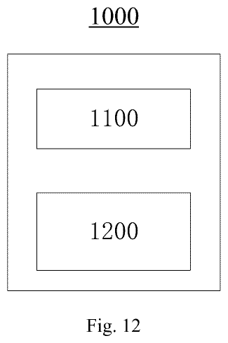

As shown in FIG. 12, at least one embodiment of the present disclosure also provides a display device 1000 including a backlight module 1100 and a display module 1200. For example, the backlight module 1100 may be the backlight module provided in any of the embodiments described above. For example, the backlight module 1100 is provided on one side of the display module 1200, and may provide backlight for the display module 1200. Because the display device 1000 includes the backlight module 1100 of any of the above-mentioned embodiments, the technical effects brought about by the above-mentioned backlight module 1100 are also present, and will not be described in detail here.

For example, the display device 1000 may be any product or component having a display function such as a television, a notebook computer, a tablet computer, a wearable display device, a cell phone, a vehicle-mounted display, a navigation, an electronic book, a digital photo frame, an advertisement light box, etc. and the embodiments of the present disclosure are not limited in this respect.

There are the following points to be clarified:
(1) The accompanying drawings of the embodiments of the present disclosure relate only to the structures involved with the embodiments of the present disclosure, and other structures can be referred to the usual design.
(2) Features in the same embodiment and different embodiments of the present disclosure may be combined with each other without conflict.

The foregoing is only an exemplary embodiment of the present disclosure and is not intended to limit the scope of protection of the present disclosure, which is determined by the appended rights.

1: A light-emitting substrate, comprising:
a base substrate;
a plurality of first drive units, located on the base substrate, wherein the plurality of first drive units are arranged in an array in a first direction and a second direction, each of the plurality of first drive units comprises a plurality of first connection portions, the first direction and the second direction are both parallel to the base substrate, and the first direction intersects with the second direction;
a second drive unit, located on the base substrate, the second drive unit comprising a second connection portion and a plurality of first leads electrically connected to the second connection portion,
wherein at least a portion of the second drive unit is located between two first drive units adjacent in the first direction, and between two first drive units adjacent in the second direction, and at least one first lead comprises a test pad, the test pad is configured to detect a signal in the first lead.

2: The light-emitting substrate according to claim 1, further comprising a plurality of first signal lines electrically connected to the second connection portion,
wherein an orthographic projection, on the base substrate, of the test pad does not overlap with an orthographic projection, on the base substrate, of each of the plurality of first signal lines.

3: The light-emitting substrate according to claim 2, wherein
the first connection portion and the first drive unit are distributed in a staggered manner in the first direction, and the first connection portion and the first drive unit are distributed in a staggered manner in the second direction.

4: The light-emitting substrate according to claim 1, wherein
in the first direction, end portions, away from the second connection portion, of the plurality of first leads in one second drive unit are all located on one side of the second connection portion, and an orthographic projection, on the base substrate, of the test pad in one first lead does not overlap with an orthographic projection, on the base substrate, of another adjacent first lead.

5: The light-emitting substrate according to claim 3, wherein
the test pad in one of the plurality of first leads does not overlap with the second connection portion in the first direction, and/or
the test pad of another one of the plurality of first leads at least partially overlaps with the second connection portion in the first direction, and is located in a spacing between two first drive units adjacent in the second direction.

6: The light-emitting substrate according to claim 3, wherein the plurality of first signal lines extend in the second direction and comprise a first conductive line, a second conductive line, a third conductive line, and a fourth conductive line; and
the second connection portion comprises a first connection end, a second connection end, a third connection end and a fourth connection end, and the plurality of first leads comprise a first connection line, a second connection line, a third connection line and a fourth connection line,
wherein the first connection end is electrically connected to the first conductive line through the first connection line, the second connection end is electrically connected to the second conductive line through the second connection line, the third connection end is electrically connected to the third conductive line through the third connection line, and the fourth connection end is electrically connected to the fourth conductive line through the fourth connection line,
at least one selected from a group consisting of the first connection line, the second connection line, and the third connection line comprises the test pad.

7: (canceled)

8: The light-emitting substrate according to claim 6, wherein in the second drive unit, the first connection end and the second connection end are adjacently provided in the first direction, and the first connection end is closer to the first conductive line adjacent to the second drive unit than the second connection end, and the first connection line is located between two first drive units adjacent in the second direction, and
an end portion, away from the second drive unit, of the first connection line comprises a first test pad, the first test pad is configured to detect an input signal, an end, away from the second drive unit, of the second connection line comprises a second test pad, the second test pad is configured to detect an output signal, and in the second direction, the first test pad and the second test pad are respectively located on two sides of the same one first connection portion.

9: The light-emitting substrate according to claim 8, wherein in the second direction, an end portion, away from the second connection portion, of the third connection line and an end portion, away from the second connection portion, of the fourth connection line are both located on one side, away from the first connection line adjacent to one first connection portion, of the same one first connection portion.

10: The light-emitting substrate according to claim 8, wherein in the second direction, the third connection line and the fourth connection line are both located between the first test pad and the second test pad.

11: The light-emitting substrate according to claim 9, wherein
the third connection line comprises a first integration portion, the fourth connection line comprises a second integration portion, the first integration portion is configured to be electrically connected to one end of a capacitor, and the second integration portion is configured to be electrically connected to the other end of the capacitor, and
in the first direction, the first integration portion and the second integration portion are both located between a portion, extending in the second direction, of the second connection line and the second conductive line electrically connected to the second connection line.

12: The light-emitting substrate according to claim 3, wherein
the second drive unit and the first drive unit are distributed in a staggered manner in the first direction,
a center of an orthographic projection, on the base substrate, of the second connection portion substantially coincides with a center of a pattern enclosed by connection lines of centers of orthographic projections, on the base substrate, of adjacent four first connection portions.

13: (canceled)

14: The light-emitting substrate according to claim 6, wherein
in the second drive unit, the first connection end and the second connection end are adjacently provided in the second direction, and the third connection end and the fourth connection end are adjacently provided in the second direction, and
an end portion, away from the second drive unit, of the first connection line comprises a first test pad, an end portion, away from the second drive unit, of the second connection line comprises a second test pad, and in the second direction, the first test pad and the second test pad are located on one side of the same one first connection portion.

15: The light-emitting substrate according to claim 14, wherein the first connection line, the second connection line, and the third connection line are all located between two first drive units adjacent in the second direction.

16: The light-emitting substrate according to claim 14, wherein
in the second direction, the third connection line is located on one side, away from the first connection line, of the second connection line; and
in the first direction, at least a portion of the fourth connection line is located on one side, away from the first conductive line, of the first connection line.

17: The light-emitting substrate according to claim 8, wherein the first drive unit comprises a plurality of first drive portions, and each of the plurality of first drive portions comprises a plurality of the first connection portions sequentially connected in series, and
the first drive unit comprises a drive connection portion, the plurality of first drive portions are arranged in an array in the first direction and the second direction, and the drive connection portion is located in a region enclosed by connection lines of centers of some of the plurality of the first connection portions adjacent to the drive connection portion,
the plurality of first drive portions comprise a first drive sub-portion, a second drive sub-portion, a third drive sub-portion, and a fourth drive sub-portion arranged in two rows and two columns, and the drive connection portion is located in a region enclosed by connection lines of centers of four first connection portions adjacent to the drive connection portion.

18: (canceled)

19: The light-emitting substrate according to claim 17, further comprising:
a plurality of second signal lines, wherein the first drive portion is electrically connected to the plurality of second signal lines, and at least one of the plurality of second signal lines is located between the first drive sub-portion and the second drive sub-portion adjacent in the first direction, and is located between the third drive sub-portion and the fourth drive sub-portion adjacent in the first direction.

20: The light-emitting substrate according to claim 17, wherein in the second direction, at least two first drive portions are provided between two second connection portions which are located in one same column and adjacent to each other.

21: The light-emitting substrate according to claim 6, wherein in the second direction, one end, away from the second connection end, of the second connection line of one second drive unit is electrically connected to one end, away from the first connection end, of the first connection line of another adjacent second drive unit, and
the light-emitting substrate further comprises a bonding region, and, in a plurality of second drive units in one same column, the first connection line of a first one of the plurality of the second drive units is electrically connected to one end of one first conductive line, and the other end of the one first conductive line is connected to the bonding region, and one end of the second connection line of a last one of the plurality of the second drive units is electrically connected to one end of one second conductive line, and the other end of the one second conductive line is connected to the bonding region.

22: A backlight module, comprising a light-emitting substrate, wherein the light-emitting substrate comprises:
a base substrate;
a plurality of first drive units, located on the base substrate, wherein the plurality of first drive units are arranged in an array in a first direction and a second direction, each of the plurality of first drive units comprises a plurality of first connection portions, the first direction and the second direction are both parallel to the base substrate, and the first direction intersects with the second direction;
a second drive unit, located on the base substrate, the second drive unit comprising a second connection portion and a plurality of first leads electrically connected to the second connection portion,
wherein at least a portion of the second drive unit is located between two first drive units adjacent in the first direction, and between two first drive units adjacent in the second direction, and at least one first lead comprises a test pad, the test pad is configured to detect a signal in the first lead.

23: A display device, comprising a backlight module, wherein the backlight module comprises a light-emitting substrate, and the light-emitting substrate comprises:
a base substrate;
a plurality of first drive units, located on the base substrate, wherein the plurality of first drive units are arranged in an array in a first direction and a second direction, each of the plurality of first drive units comprises a plurality of first connection portions, the first direction and the second direction are both parallel to the base substrate, and the first direction intersects with the second direction;
a second drive unit, located on the base substrate, the second drive unit comprising a second connection portion and a plurality of first leads electrically connected to the second connection portion,
wherein at least a portion of the second drive unit is located between two first drive units adjacent in the first direction, and between two first drive units adjacent in the second direction, and at least one first lead comprises a test pad, the test pad is configured to detect a signal in the first lead.
